(19) United States
(12) Patent Application Publication
(10) Pub. No.: US 2025/0359352 A1
(43) Pub. Date: Nov. 20, 2025

(54) METHODS OF MAKING A PHOTOVOLTAIC MODULE

(71) Applicant: GAF Energy LLC, Parsippany, NJ (US)

(72) Inventors: Richard Perkins, San Jose, CA (US); Thierry Nguyen, San Francisco, CA (US); Gabriela Bunea, San Jose, CA (US); David Kavulak, San Francisco, CA (US); Gary Rossi, San Francisco, CA (US); Caleb Cheung, San Jose, CA (US)

(21) Appl. No.: 19/212,377

(22) Filed: May 19, 2025

Related U.S. Application Data
(60) Provisional application No. 63/649,838, filed on May 20, 2024.

(51) Int. Cl. H10F 19/80

(52) U.S. Cl. CPC H10F 19/807; H10F 19/804

(57) ABSTRACT

A method, including obtaining a plurality of components, including at least a frontsheet, solar cells, and a backsheet; positioning the plurality of components such that a first row of solar cells is above the backsheet, a second row of solar cells is above the backsheet, and the frontsheet is above at least one of the first row of solar cells or the second row of solar cells; and laminating the plurality of components to form a photovoltaic module. The photovoltaic module includes a first portion and a second portion, where the first portion of the photovoltaic module includes the first row of solar cells, where the second portion of the photovoltaic module includes the second row of solar cells, where the first portion of the photovoltaic module extends along a first plane, where the second portion of the photovoltaic module extends along a second plane, and where the second plane is offset from the first plane.

### CROSS-REFERENCE TO RELATED APPLICATION

This application is a Section 111(a) application relating to and claiming the benefit of commonly owned, co-pending U.S. Provisional Patent Application Ser. No. 63/649,838, filed May 20, 2024, entitled “METHODS OF FORMING A PHOTOVOLTAIC MODULE,” the contents of which is incorporated herein by reference in its entirety.

### FIELD

The present disclosure is directed to a photovoltaic module, and, more specifically, to methods of forming the photovoltaic module that is installed on a roof deck.

### BACKGROUND

In a known roofing system, one or more photovoltaic modules are installed on a roof deck, such as a steep slope roof deck. In some roofing systems, the photovoltaic modules, each of which includes at least one solar cell, are installed on the roof deck adjacent one or more roofing shingles that do not include any solar cells.

### SUMMARY

The Claims, rather than the Summary, define covered embodiments of the present invention. The Summary is a high-level overview of various aspects of the invention, and introduces some concepts that are further described in the Detailed Description below. The Summary is not intended to identify key or essential features of the claimed subject matter, and also is not intended to be used in isolation to determine the scope of the claimed subject matter. Instead, the claimed subject matter should be understood by reference to appropriate portions of the Specification and drawings, as well as to each claim.

In some embodiments, the present invention provides a method, comprising: obtaining a plurality of components, wherein the plurality of components comprises at least: a frontsheet, solar cells, and a backsheet; positioning the plurality of components such that: a first row of solar cells is above the backsheet, a second row of solar cells is above the backsheet, and the frontsheet is above at least one of the first row of solar cells or the second row of solar cells; and laminating the plurality of components to form a photovoltaic module, wherein the photovoltaic module includes a first portion and a second portion, wherein the first portion of the photovoltaic module includes the first row of solar cells, wherein the second portion of the photovoltaic module includes the second row of solar cells, wherein the first portion of the photovoltaic module extends along a first plane, wherein the second portion of the photovoltaic module extends along a second plane, and wherein the second plane is offset from the first plane, thereby forming a wireway in the second plane.

In some embodiments, the laminating comprises laminating at a temperature of 140 degrees C. to 180 degrees C.

In some embodiments, the laminating comprises laminating at a pressure of 0.5 bar to 1 bar.

In some embodiments, the backsheet comprises a polymer material.

In some embodiments, the backsheet comprises at least one of a polyolefin elastomer (POE), a dielectric material, a thermoplastic polyolefin (TPO), or a continuous fiber tape (CFT).

In some embodiments, the frontsheet comprises: a polymer layer, and a glass layer, wherein the polymer layer is an outer layer of the photovoltaic module.

In some embodiments, the polymer layer comprises at least one of an ethylene tetrafluoroethylene (ETFE) or a polyolefin elastomer (POE).

In some embodiments, the present invention provides a method, comprising: obtaining a plurality of components, wherein the plurality of components comprises at least: a frontsheet, solar cells, and a backsheet; positioning the plurality of components such that: a first row of solar cells is above the backsheet, a second row of solar cells is above the backsheet, and the frontsheet is above at least one of the first row of solar cells or the second row of solar cells; and vacuum forming the plurality of components with one another to form a photovoltaic module, wherein the photovoltaic module has a first portion and a second portion, wherein the first portion of the photovoltaic module includes the first row of solar cells, wherein the second portion of the photovoltaic module includes the second row of solar cells, wherein the first portion of the photovoltaic module extends along a first plane wherein the second portion of the photovoltaic module extends along a second plane, and wherein the second plane is offset from the first plane, thereby forming a wireway in the second plane.

In some embodiments, the vacuum forming comprises vacuum forming at a temperature of 140 degrees C. to 180 degrees C.

In some embodiments, the vacuum forming comprises vacuum forming at a pressure of 0.5 bar to 1 bar.

In some embodiments, the present invention provides a method, comprising: obtaining a plurality of components, wherein the plurality of components comprises at least: a frontsheet, solar cells, and a backsheet; positioning the plurality of components such that: a first row of solar cells is above a first portion of the backsheet, a second row of solar cells is above a second portion of the backsheet, and the frontsheet is above at least one of the first row of solar cells and the second row of solar cells; laminating the plurality of components to form a photovoltaic module, wherein the photovoltaic module has a first portion and a second portion, wherein the first portion includes the first row of solar cells, wherein the second portion includes the second row of solar cells; heating the photovoltaic module, thereby providing a heated photovoltaic module; and thermoforming the heated photovoltaic module, thereby positioning the second portion of the photovoltaic module relative to the first portion such that: the first portion of the photovoltaic module extends along a first plane, and the second portion of the photovoltaic module extends along a second plane, wherein the second plane is offset from the first plane, thereby forming a wireway in the second plane.

In some embodiments, the laminating comprises laminating at a temperature of 140 degrees C. to 180 degrees C.

In some embodiments, the laminating comprises laminating at a pressure of 0.5 bar to 1 bar.

In some embodiments, the heating the photovoltaic module comprises heating to a temperature of 140 degrees C. to 180 degrees C.

In some embodiments, the method includes, prior to the heating the photovoltaic module, cooling the photovoltaic module.

In some embodiments, the cooling the photovoltaic module comprises cooling to a temperature of 80 degrees C. to 120 degrees C.

In some embodiments, the thermoforming comprises vacuum thermoforming.

In some embodiments, the thermoforming comprises vacuum thermoforming at a temperature of 120 degrees C. to 160 degrees C., and/or a pressure of 0.5 bar to 1 bar.

In some embodiments, the thermoforming comprises mechanical thermoforming.

In some embodiments, the thermoforming comprises mechanical thermoforming at a temperature of 120 degrees C. to 160 degrees C., and/or a pressure of 0.5 bar to 2 bar.

### BRIEF DESCRIPTION OF THE DRAWINGS

This section refers to the drawings that form a part of this disclosure, and which illustrate some of the embodiments of structure, materials, and/or methods of the present invention described herein.

FIG. 1 is a schematic top view of a photovoltaic module, in accordance with some embodiments of the invention.

FIG. 2 is a schematic side cross-sectional view of components of the photovoltaic module of FIG. 1, prior to lamination of the components with one another, in accordance with some embodiments of the invention.

FIG. 3 is a block diagram of a method of manufacturing the photovoltaic module of FIGS. 1 and 2, in accordance with some embodiments of the invention.

FIG. 4 is a schematic side cross-sectional view of the components of the photovoltaic module, prior to vacuum thermoforming of the components with one another, in accordance with some embodiments of the invention.

FIG. 5 is a block diagram of a method of manufacturing the photovoltaic module of FIG. 4, in accordance with some embodiments of the invention.

FIG. 6 is a schematic side cross-sectional view of the components of the photovoltaic module, after laminating the components with one another to form the photovoltaic module, but before forming the wireway, in accordance with some embodiments of the invention.

FIG. 7 is a schematic side cross-sectional view of the components of the photovoltaic module of FIG. 6, while forming the wireway, in accordance with some embodiments of the invention.

FIG. 8 is a block diagram of a method of manufacturing the photovoltaic module of FIGS. 6 and 7, in accordance with some embodiments of the invention.

FIGS. 9A and 9B are schematic views of some embodiments of a method of making a photovoltaic module and the photovoltaic module.

FIGS. 10A and 10B are schematic views of some embodiments of a method of making a photovoltaic module and the photovoltaic module.

FIGS. 11A and 11B are views of some embodiments of a photovoltaic module.

### DETAILED DESCRIPTION

In addition to the benefits and improvements that the Specification discloses, other objects and advantages that the Specification provides will become apparent from the following description taken in conjunction with the accompanying figures. Although the description discloses and describes detailed embodiments of the present disclosure, the disclosed embodiments are merely illustrative of the disclosure that may be embodied in various forms. In addition, each of the examples given regarding the various embodiments of the disclosure are intended to be illustrative, and not restrictive.

As used herein, a “steep slope” roof or roof deck is a roof or roof deck that has a pitch of Y/X, where Y and X are in a ratio of 4:12 to 20:12, where Y corresponds to the “rise” of the roof or roof deck, and where X corresponds to the “run” of the roof or roof deck.

As used herein, a “sloped” roof or roof deck is a roof or roof deck that has a pitch greater than zero (e.g., the roof or roof deck is not flat), but the pitch is less than that of a steep slope roof or roof deck.

In some embodiments, the present invention provides a method, such as a method of manufacturing and/or a method of installing one or more (e.g., one, or a plurality of) photovoltaic modules. In some embodiments, the present invention provides a roofing system including the one or more photovoltaic modules. In some embodiments, one or more of the photovoltaic modules are installed on a roof deck. In some embodiments, the roof deck is a sloped roof deck. In some embodiments, the sloped roof deck is a steep slope roof deck. In some embodiments, the one or more photovoltaic modules are installed on the roof deck, and one or more roofing shingles also are installed on the roof deck.

In some embodiments, except as otherwise shown or described herein, one or more of the photovoltaic modules includes a structure, composition, component, and/or function similar to those of one or more embodiments of the photovoltaic or solar modules or shingles disclosed, shown, and/or described in any or all of: U.S. application Ser. No. 17/831,307, filed Jun. 2, 2022, titled “Roofing Module System,” and published under U.S. Patent Application Publication No. 2022-0393637 on Dec. 8, 2022; U.S. application Ser. No. 18/169,718, filed Feb. 15, 2023, titled “Roofing Module System,” and published under U.S. Patent Application Publication No. 2023-0203815 on Jun. 29, 2023; PCT International Patent Publication No. WO 2022/051593, Application No. PCT/US2021/049017, published Mar. 10, 2022, titled “Building Integrated Photovoltaic System,” owned by GAF Energy LLC; and/or U.S. Pat. No. 11,251,744 to Bunea et al., issued Feb. 15, 2022, titled “Photovoltaic Shingles and Methods of Installing Same”; and the disclosures of each of which are incorporated by reference herein in their entireties, with certain different and/or additional features as described herein.

In some embodiments, except as otherwise shown or described herein, one or more of the roofing shingles includes a structure, composition, component, and/or function similar to those of one or more embodiments of a non-photovoltaic module and/or another roofing material disclosed, shown, and/or described in either or both of U.S. application Ser. No. 17/831,307, filed Jun. 2, 2022, titled “Roofing Module System,” and published under U.S. Patent Application Publication No. 2022-0393637 on Dec. 8, 2022; and/or U.S. application Ser. No. 18/169,718, filed Feb. 15, 2023, titled “Roofing Module System,” and published under U.S. Patent Application Publication No. 2023-0203815 on Jun. 29, 2023; and/or U.S. application Ser. No. 18/352,894, filed Jul. 14, 2023, titled “Solar Roofing System with Fiber Composite Roofing Shingles”; and the disclosures of each of which are incorporated by reference herein in their entireties, with certain different and/or additional features as described herein.

In some embodiments, the roofing system or method includes an underlayment installed between the roof deck and the one or more photovoltaic modules and/or the one or more roofing shingles. In some embodiments, the roofing system or method does not include an underlayment. In some embodiments, the roofing system or method includes one or more components other than and/or in addition to the one or more photovoltaic modules, the one or more roofing shingles, and/or the underlayment installed on the roof deck.

In some embodiments, after manufacture, a portion of the photovoltaic module extends along a first plane, and another portion of the photovoltaic module extends along a second plane. In some embodiments, the second plane is offset from the first plane, thereby forming a wireway in the second plane. In some embodiments, the offset is a vertical offset—e.g., the first plane is at a first elevation when the photovoltaic module is placed on a surface (and/or when the photovoltaic module is installed on the roof deck), and the second plane is at a second elevation when the photovoltaic module is placed on the surface (and/or when the photovoltaic module is installed on the roof deck), such that the planes and portions are vertically offset from one another.

In some embodiments, a first portion of the photovoltaic module extends along the first plane. In some embodiments, a second portion of the photovoltaic module extends along the second plane. In some embodiments, the first portion includes at least one solar cell. In some embodiments, the first portion includes a plurality of solar cells. In some embodiments, the first portion includes a plurality of solar cells in a first row of solar cells. In some embodiments, the first portion includes more than one row of solar cells, and one or more of the rows include more than one solar cell.

In some embodiments, the second portion includes at least one solar cell. In some embodiments, the second portion includes a plurality of solar cells. In some embodiments, the second portion includes a plurality of solar cells in a second row of solar cells. In some embodiments, the second portion includes more than one row of solar cells, and one or more of the rows include more than one solar cell.

In some embodiments, the first portion of the photovoltaic module extends along the first plane, and the second portion of the photovoltaic module extends along an arch elevated above the first plane. In some embodiments, after manufacture, the portion of the photovoltaic module extends along the first plane, and another portion of the photovoltaic module extends along the arch elevated above the first plane. In some embodiments, the arch is offset from the first plane, thereby forming the wireway. In some embodiments, the offset is a vertical offset—e.g., the first plane is at a first elevation when the photovoltaic module is placed on a surface (and/or when the photovoltaic module is installed on the roof deck), and at least a portion of the arch is at a second elevation when the photovoltaic module is placed on the surface (and/or when the photovoltaic module is installed on the roof deck).

In some embodiments, the photovoltaic module includes a backsheet. In some embodiments, the at least one solar cell in the first portion is above the backsheet. In some embodiments, the first row of solar cells is above the backsheet. In some embodiments, the at least one solar cell in the second portion is above the backsheet. In some embodiments, the second row of solar cells is above the backsheet.

In some embodiments, the photovoltaic module includes a frontsheet. In some embodiments, the frontsheet is above the at least one solar cell in the first portion. In some embodiments, the frontsheet is above the first row of solar cells. In some embodiments, the frontsheet is above the at least one solar cell in the second portion. In some embodiments, the frontsheet is above the second row of solar cells. In some embodiments, the frontsheet is above both the at least one solar cell in the first portion as well as the at least one solar cell in the second portion. In some embodiments, the frontsheet is above only one of the at least one solar cell included in the first portion or the at least one solar cell included in the second portion. In some embodiments, the photovoltaic module includes more than one frontsheet—e.g., a first frontsheet and a second frontsheet. In some embodiments, the first frontsheet is above the at least one solar cell in the first portion. In some embodiments, the first frontsheet is above the first row of solar cells. In some embodiments, the second frontsheet is above the at least one solar cell in the second portion. In some embodiments, the second frontsheet is above the second row of solar cells.

In some embodiments, the present invention provides a method. In some embodiments, the present invention provides a method of manufacturing the photovoltaic module. In some embodiments, the method of manufacture includes obtaining a plurality of components, wherein the plurality of components includes one or more, or all of, the frontsheet, solar cells, and/or the backsheet. In some embodiments, the plurality of components includes one or more other components, in addition to and/or in place of any or all of the frontsheet, the first row of solar cells, the second row of solar cells, and/or the backsheet.

In some embodiments, the method includes positioning the plurality of components such that: the frontsheet is above at least one of the first row of solar cells and/or the second row of solar cells; the first row of solar cells is above the backsheet; and/or the second row of solar cells is above the backsheet.

In some embodiments, the method includes laminating the plurality of components to one another. In some embodiments, the laminating forms the photovoltaic module. In some embodiments, the photovoltaic module includes the first portion and the second portion. In some embodiments, the first portion of the photovoltaic module includes the first row of solar cells. In some embodiments, the second portion of the photovoltaic module includes the second row of solar cells. In some embodiments, the first portion of the photovoltaic module extends along the first plane. In some embodiments, the second portion of the photovoltaic module extends along the second plane. In some embodiments, the second plane is offset from the first plane, thereby forming the wireway in the second plane. In some embodiments, the offset is a vertical offset. Thus, in some embodiments, the wireway is formed during the laminating of the components with one another.

In some embodiments, the wireway is a location in which is disposed, located, or positioned one or more of electronics, wires, and/or other electrical or other components associated with one or more of the photovoltaic module and/or a roofing system that includes the photovoltaic module, when the photovoltaic module in installed on the roof deck.

In some embodiments, the laminating of the components occurs at a temperature of 140 degrees C. to 180 degrees C.

In some embodiments, the laminating of the components occurs at a pressure of 0.5 bar to 1 bar.

In some embodiments, the backsheet includes a polymer material. In some embodiments, the backsheet includes at least one of a polyolefin elastomer (POE), a dielectric material, a thermoplastic polyolefin (TPO), ethylene tetrafluoroethylene (ETFE), and/or a continuous fiber tape (CFT), and/or combinations thereof. In some embodiments, the CFT is as shown and/or described in one or more of the patents, applications, or publications incorporated by reference herein.

In some embodiments, the frontsheet includes a single layer. In some embodiments, the frontsheet includes multiple layers. In some embodiments, the multiple layers include two or more layers. In some embodiments, the two or more layers includes three layers, four layers, five layers, six layers, or more than six layers. In some embodiments, the frontsheet includes a polymer layer and a glass layer. In some embodiments, the polymer layer is an outer layer of the photovoltaic module. In some embodiments, the glass layer is the closest layer of the frontsheet to the solar cells. In some embodiments, the frontsheet includes an adhesive layer between the polymer layer and the glass layer. In some embodiments, the single- or multiple-layer frontsheet is as shown and/or described in one or more of the patents, applications, and/or publications incorporated by reference herein.

In some embodiments, the polymer layer includes at least one of a dielectric material and/or layer, a thermoplastic polyolefin (TPO) material and/or layer, and/or a continuous fiber tape (CFT) material and/or layer, and/or combinations thereof.

In some embodiments, the adhesive layer includes a polyolefin elastomer (POE). In some embodiments, the adhesive layer includes an adhesive as shown and/or described in one or more of the patents, applications, and/or publications incorporated by reference herein.

In some embodiments, one or more of the solar cells, and/or one or more of the rows of solar cells, are encapsulated. In some embodiments, the encapsulant completely covers (e.g., completely encapsulates) the one or more solar cells and/or or the one or more rows of solar cells. In some embodiments, the encapsulant at least partially covers the one or more solar cells and/or or the one or more rows of solar cells. In some embodiments, the encapsulant and/or the encapsulated solar cells are as shown and/or described in one or more of the patents, applications, and/or publications incorporated by reference herein.

In some embodiments, the photovoltaic module includes one or more electrical components. In some embodiments, the photovoltaic module includes a junction box. In some embodiments, the photovoltaic module includes a power optimizer. In some embodiments, the photovoltaic module includes a power junction module. In some embodiments, the photovoltaic module includes one or more bypass diodes. In some embodiments, the photovoltaic module includes a rapid shutdown device. In some embodiments, the photovoltaic module includes one or more of a communication receiver and/or transmitter. In some embodiments, the photovoltaic module includes one or more connectors. In some embodiments, the photovoltaic module includes one or more bypass diodes photovoltaic wires.

In some embodiments, one or more of the electrical components are as shown and/or described in one or more of the patents, applications, and/or publications incorporated by reference herein.

In some embodiments, the present invention provides a method, including obtaining the plurality of components, positioning the plurality of components, such as on one another, and vacuum forming the plurality of components with one another to form the photovoltaic module. In some embodiments, the photovoltaic module includes the first portion and the second portion. In some embodiments, the first portion of the photovoltaic module includes the first row of solar cells. In some embodiments, the second portion of the photovoltaic module includes the second row of solar cells. In some embodiments, the first portion of the photovoltaic module extends along the first plane. In some embodiments, the second portion of the photovoltaic module extends along the second plane. In some embodiments, the second plane is offset from the first plane, thereby forming the wireway in the second plane. In some embodiments, the offset is a vertical offset. Thus, in some embodiments, the wireway is formed during the vacuum forming of the components with one another.

In some embodiments, the vacuum forming of the components occurs at a temperature of 140 degrees C. to 180 degrees C.

In some embodiments, the vacuum forming of the components occurs at a pressure of 0.5 bar to 1 bar.

In some embodiments, the present invention provides a method including obtaining the plurality of components, positioning the plurality of components, such as on one another, and laminating the plurality of components to form the photovoltaic module. In some embodiments, the photovoltaic module has the first portion including the at least one solar cell and/or the first row of solar cells, and the second portion including the at least one solar cell and/or the second row of solar cells. In some embodiments, the first portion and the second portion are not yet offset from one another after the laminating of the components with one another. In some embodiments, the photovoltaic module does not yet include the wireway after laminating.

In some embodiments, the method further includes heating the photovoltaic module formed by the components laminated to one another, thereby forming a heated photovoltaic module. In some embodiments, the method includes thermoforming the heated photovoltaic module, during which at least a portion of the heated photovoltaic module is repositioned relative to another portion of the heated photovoltaic module. In some embodiments, the repositioning includes repositioning the second portion of the photovoltaic module relative to the first portion such that the first portion of the photovoltaic module extends along the first plane, and the second portion of the photovoltaic module extends along the second plane, wherein the second plane is offset from the first plane, thereby forming the wireway in the second plane. In some embodiments, the offset is a vertical offset.

In some embodiments, the laminating of the components occurs at a temperature of 140 degrees C. to 180 degrees C.

In some embodiments, the laminating of the components occurs at a pressure of 0.5 bar to 1 bar.

In some embodiments, the heating of the laminated photovoltaic module occurs at a temperature of 140 degrees C. to 180 degrees C.

In some embodiments, after the laminating the components and prior to the heating the photovoltaic module, the method includes cooling the photovoltaic module.

In some embodiments, the laminated photovoltaic module is cooled to a temperature of 80 degrees C. to 120 degrees C.

In some embodiments, the thermoforming includes vacuum thermoforming.

In some embodiments, the vacuum thermoforming occurs at a temperature of 120 degrees C. to 160 degrees C.

In some embodiments, the vacuum thermoforming occurs at a pressure of 0.5 bar to 1 bar.

In some embodiments, the thermoforming includes mechanical thermoforming.

In some embodiments, the mechanical thermoforming occurs at a temperature of 120 degrees C. to 160 degrees C.

In some embodiments, the mechanical thermoforming occurs at a pressure of 0.5 bar to 2 bar.

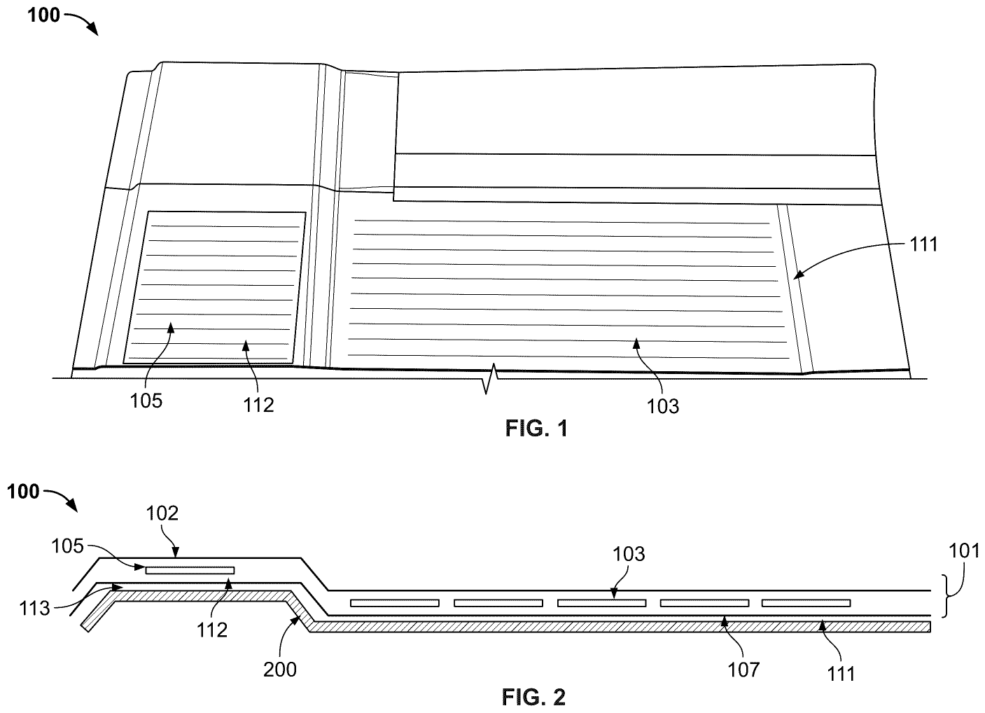

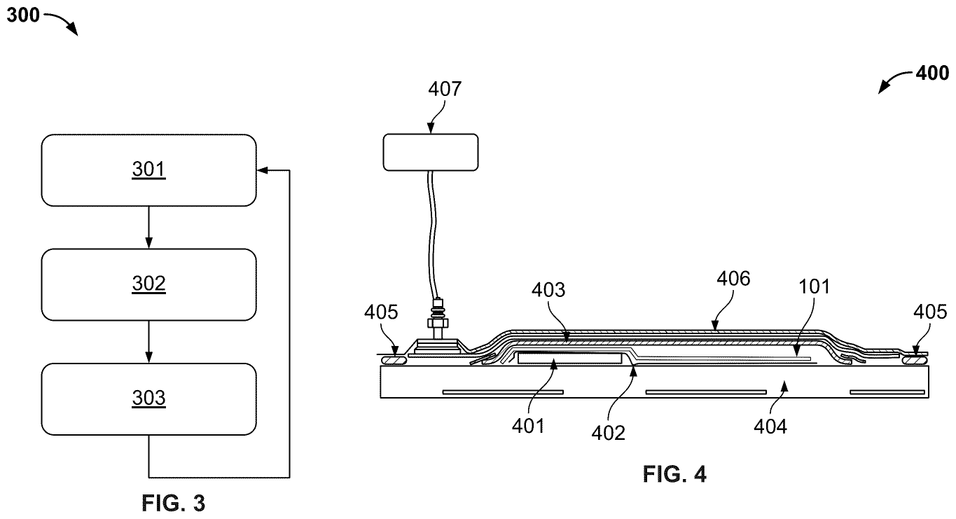

With reference to the drawings, FIG. 1 shows a schematic top view of a photovoltaic module 100, FIG. 2 shows a schematic side cross-sectional view of components 101 of the photovoltaic module 100 of FIG. 1, prior to lamination of the components 101 with one another, and FIG. 3 shows a block diagram of a method of manufacturing the photovoltaic module 100 of FIGS. 1 and 2, in accordance with some embodiments of the invention. As FIGS. 1 and 2 show, in some embodiments, the photovoltaic module 100 includes the components 101 positioned on top of one another, the components 101 including one or more of a frontsheet 102, a first row of solar cells 103, a second row of solar cells 105, and/or a backsheet 107. In some embodiments, the components 101 include other and/or additional components, as discussed. In some embodiments, one or more of the frontsheet 102, the first row of solar cells 103, the second row of solar cells 105, and/or the backsheet 107 is in accordance with the above descriptions. As the figures show, in some embodiments, the frontsheet 102 is positioned above at least one of the first row of solar cells 103 and/or the second row of solar cells 105, the first row of solar cells 103 is positioned above the backsheet 107, and the second row of solar cells 105 is positioned above the backsheet 107.

In some embodiments, the components 101 are laminated to form the photovoltaic module 100. As FIGS. 1 and 2 show, in some embodiments, the components 101 are laminated such that the photovoltaic module 100 includes a first portion 111 and a second portion 112. As shown, in some embodiments, the first portion 111 of the photovoltaic module 100 includes the first row of solar cells 103, and the second portion 112 of the photovoltaic module 100 includes the second row of solar cells 105. In some embodiments, the first portion 111 of the photovoltaic module 100 extends along a first plane, and the second portion 112 of the photovoltaic module 100 extends along a second plane, where the second plane is offset from the first plane, thereby forming a wireway 113 in the second plane, by offsetting the first plane relative to the second plane. Thus, in some embodiments, during the lamination of the components 101 to one another, the wireway 113 is formed.

In some embodiments, as FIG. 2 shows, the components 101 are positioned and laminated on a tray 200. In some embodiments, the tray 200 is metal. In some embodiments, the metal is at least one of, but is not limited to, aluminum, iron, steel such as stainless steel, copper, and/or zinc, and/or combinations thereof. In some embodiments, the tray 200 is a non-metal. In some embodiments, the non-metal is a polymer. In some embodiments, the polymer is a high-temperature polymer. In some embodiments, the high temperature polymer is at least one of, but is not limited to, silicone and/or a composite. In some embodiments, the composite is a glass-reinforced epoxy laminate material, such as but not limited to FR-4. In some embodiments, based on a shape of the tray 200, a shape of the wireway 113 is one or more of trapezoidal, rectangular, square, and/or arched in cross-section.

In some embodiments, either or both of the first row of solar cells 103 and/or the second row of solar cells 105 are partially or fully encapsulated in an encapsulant, as described in one or more of the patents, applications, and/or publications incorporated by reference herein. In some embodiments, the frontsheet 102 is a single layer or multilayer frontsheet, as described in one or more of the patents, applications, or publications incorporated by reference herein. In some embodiments, the backsheet 107 is a single layer or multilayer backsheet, as described in one or more of the patents, applications, and/or publications incorporated by reference herein. In some embodiments, the components 101 include other components, as described in one or more of the patents, applications, and/or publications incorporated by reference herein.

In some embodiments, as shown in FIG. 3, a method 300 includes positioning 301 the components 101 including one or more of the frontsheet 102, the first row of solar cells 103, the second row of solar cells 105, and/or the backsheet 107, on the tray 200, as discussed. In some embodiments, the method 300 includes laminating 302 the components 101 to one another, thereby forming the photovoltaic module 100 with the first portion 111 on the first plane, and the second portion 112 on the second plane, where the first plane is offset relative to the second plane, to form the wireway 113, as discussed. In some embodiments, the method 300 further includes removing 303 the photovoltaic module 100 from the tray 200. In some embodiments, the method 300 includes repeating the steps of the positioning 301, the laminating 302, and the removing 303, with the same tray 200, to form another photovoltaic module 100. In some embodiments, the method 300 includes repeating the steps of the positioning 301, the laminating 302, and the removing 303, with a different tray, to form another photovoltaic module 100.

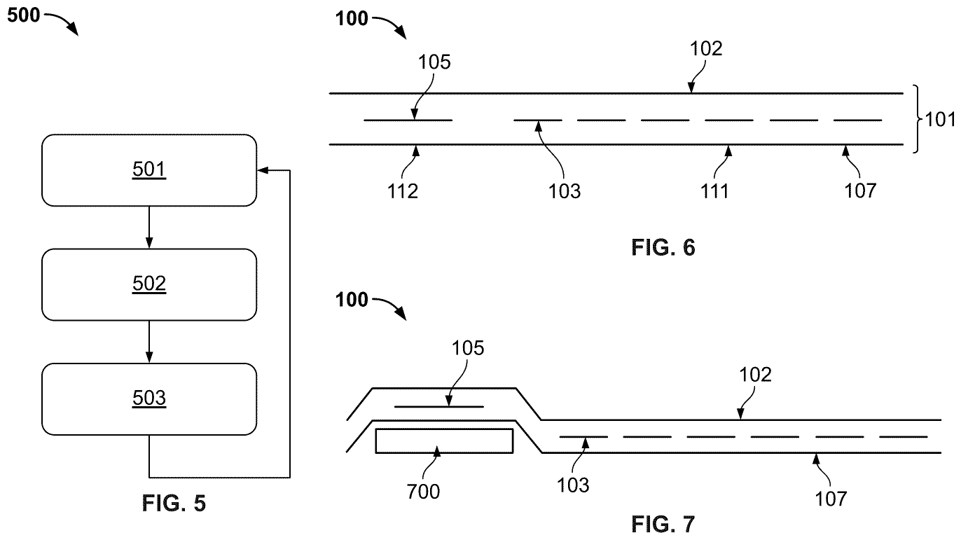

With reference to the drawings, FIG. 4 shows a schematic side cross-sectional view of the components 101 of the photovoltaic module 100, prior to vacuum thermoforming of the components 101 with one another, and FIG. 5 shows a block diagram of a method of manufacturing the photovoltaic module 100 of FIG. 4, in accordance with some embodiments of the invention.

In some embodiments, as discussed, the photovoltaic module 100 includes the components 101 positioned on top of one another, the components including one or more of the frontsheet 102, the first row of solar cells 103, the second row of solar cells 105, and/or the backsheet 107, as FIG. 2 shows, for example. In some embodiments, the components 101 are in accordance with the above descriptions. In some embodiments, the frontsheet 102 is positioned above at least one of the first row of solar cells 103 and/or the second row of solar cells 105, the first row of solar cells 103 is positioned above the backsheet 107, and/or the second row of solar cells 105 is positioned above the backsheet 107.

In some embodiments, as FIG. 4 shows, the components 101 are positioned and vacuum thermoformed in a vacuum-thermoforming device 400. In some embodiments, the vacuum-thermoforming device 400 includes a mold 401, on which the components 101 are positioned. In some embodiments, the vacuum-thermoforming device 400 includes a buffing fabric 402, covering the mold 401. In some embodiments, as FIG. 4 shows, the components 101 are positioned on the buffing fabric 402. In some embodiments, the vacuum-thermoforming device 400 includes a bleeder fabric 403, which is fastened to a surface 404 by sealant tape 405, and the bleeder fabric 403 covers the components 101. In some embodiments, as FIG. 4 shows, the vacuum-thermoforming device 400 includes a bagging film 406 that covers the bleeder fabric 403. In some embodiments, as shown in FIG. 4, the vacuum-thermoforming device 400 includes a vacuum apparatus 407, which is coupled to the bagging film 406 such as by a valve arrangement. In some embodiments, the components 101 are vacuum formed in the vacuum-thermoforming device 400 (e.g., the components 101 are subject to a vacuum and are heated), thereby forming the first portion 111 of the photovoltaic module 100 extending along the first plane, and the second portion 112 of the photovoltaic module 100 extending along the second plane, as well as forming the wireway 113 in the second plane that is offset from the first plane. Thus, in some embodiments, the wireway 113 is formed during vacuum forming of the components 101 to one another.

In some embodiments, as shown in FIG. 5, a method 500 includes positioning 501 the components 101 including one or more of the frontsheet 102, the first row of solar cells 103, the second row of solar cells 105, and/or the backsheet 107, within the vacuum-thermoforming device 400, as discussed. In some embodiments, the method 500 includes vacuum thermoforming 502 the components 101 to one another, such that the first portion 111 of the photovoltaic module 100 is in the first plane, and the second portion 112 of the photovoltaic module 100 is in the second plane, where the first plane is offset relative to the second plane, thereby forming the wireway 113, as discussed. In some embodiments, the method 500 further includes removing 503 the photovoltaic module 100 from the vacuum-thermoforming device 400. In some embodiments, the method 500 includes repeating the steps of the positioning 501, the vacuum thermoforming 502, and the removing 503, with other components 101, to form another photovoltaic module 100.

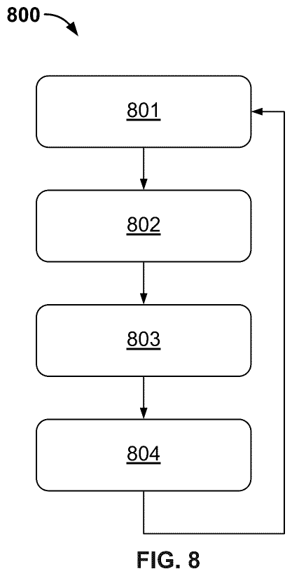

With reference to the drawings, FIG. 6 shows a schematic side cross-sectional view of the components 101 of the photovoltaic module 100, after laminating the components 101 with one another to form the photovoltaic module 100, but before forming the wireway 113; FIG. 7 shows a schematic side cross-sectional view of the components 101 of the photovoltaic module 100 of FIG. 6, while forming the wireway 113; and FIG. 8 shows a block diagram of a method of manufacturing the photovoltaic module 100 of FIG. 6, in accordance with some embodiments of the invention.

As FIGS. 6-8 show, in some embodiments, the photovoltaic module 100 includes the components 101 positioned on top of one another, the components 101 including one or more of the frontsheet 102, the first row of solar cells 103, the second row of solar cells 105, and/or the backsheet 107. In some embodiments, one or more of the frontsheet 102, the first row of solar cells 103, the second row of solar cells 105, and/or the backsheet 107 is in accordance with the above descriptions. As the figures show, in some embodiments, the frontsheet 102 is positioned above at least one of the first row of solar cells 103 and/or the second row of solar cells 105, the first row of solar cells 103 is positioned above the backsheet 107, and/or the second row of solar cells 105 is positioned above the backsheet 107.

In some embodiments, as FIG. 6 shows, the components 101 are laminated such that the photovoltaic module 100 includes the first portion 111 and the second portion 112. As shown, in some embodiments, the first portion 111 of the photovoltaic module 100 includes the first row of solar cells 103, and the second portion 112 of the photovoltaic module 100 includes the second row of solar cells 105. In some embodiments, the first portion 111 and the second portion 112 of the photovoltaic module 100 extend along a same plane (e.g., are coplanar), such that the first portion 111 is not yet offset from the second portion 112, and such that the wireway 113 is not yet provided.

In some embodiments, as FIG. 7 shows, the photovoltaic module 100, in which the components 101 have been laminated to one another, is positioned on a tray 700. In some embodiments, the tray 700 is metal. In some embodiments, the metal is at least one of, but is not limited to, aluminum, iron, steel such as stainless steel, copper, and/or zinc, and/or combinations thereof. In some embodiments, the tray 700 is a non-metal. In some embodiments, the non-metal is polymer. In some embodiments, the polymer is a high-temperature polymer. In some embodiments, the high temperature polymer is at least one of but is not limited to silicone and/or a composite. In some embodiments, the composite is a glass-reinforced epoxy laminate material, such as but not limited to FR-4.

In some embodiments, the photovoltaic module 100 is heated, and the heated photovoltaic module 100 is thermoformed, during which the first portion 111 of the photovoltaic module 100 is repositioned relative to the second portion 112 of the photovoltaic module 100. In some embodiments, the first portion 111 and the second portion 112 are repositioned such the second plane along which the second portion 112 extends is offset, such as for example vertically offset, from the first plane along which the first portion 111 extends, thereby forming the wireway 113 in the second plane.

In some embodiments, as shown in FIG. 8, a method 800 includes positioning 801 the components 101 including one or more of the frontsheet 102, the first row of solar cells 103, the second row of solar cells 105, and/or the backsheet 107 on one another. In some embodiments, the method 800 includes laminating 802 the components 101 to one another, thereby forming the photovoltaic module 100 such that the first portion 111 is on the first plane, and the second portion 112 is on the second plane, where the first plane and the second plane are substantially coplanar. In some embodiments, the method 800 further includes heating 803 the photovoltaic module 100. In some embodiments, the method 800 includes thermoforming 804 the heated photovoltaic module 100, thereby repositioning the second portion 112 relative to the first portion 111, such that the first plane is offset relative to the second plane, thereby forming the wireway 113. In some embodiments, the method 800 includes repeating the positioning 801, the laminating 802, the heating 803, and the thermoforming 804, to form another photovoltaic module 100.

In some embodiments, the method 800 includes cooling the laminated photovoltaic module 100 (e.g., the method 800 includes a cooling step between the laminating 802 and the heating 803).

In some embodiments, the thermoforming 804 includes vacuum thermoforming, as discussed. In some embodiments, the thermoforming 804 includes mechanical thermoforming, as discussed.

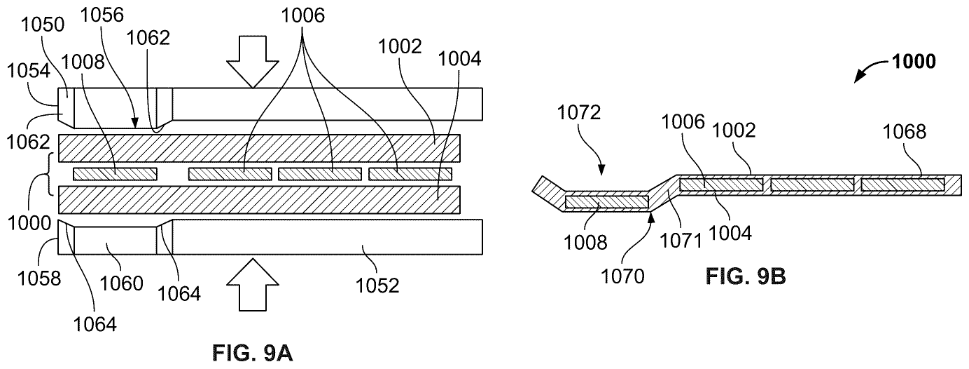

FIGS. 9A and 9B illustrate embodiments of a method of making a photovoltaic module 1000. In some embodiments, the photovoltaic module 1000 has a structure, composition, function, and features similar to the photovoltaic modules described above, except as otherwise noted. In some embodiments, the method includes providing a first layer 1002. In some embodiments, the first layer 1002 is a frontsheet of the photovoltaic module 1000. In some embodiments, the first layer 1002 is composed of a polymer. In some embodiments, the first layer 1002 is composed of a composite material. In some embodiments, the first layer 1002 is composed of a prepreg composite material. In some embodiments, the prepreg composite material includes a reinforcing fabric, such as carbon fiber or fiberglass pre-impregnated with a resin system, such as epoxy.

In some embodiments, the method includes providing a second layer 1004. In some embodiments, the second layer 1004 is a backsheet of the photovoltaic module 1000. In some embodiments, the second layer 1004 is below the first layer 1002. In some embodiments, the second layer 1004 is composed of a polymer. In some embodiments, the second layer 1004 is composed of a composite material. In some embodiments, the second layer 1004 is composed of a prepreg composite material, such as the above-referenced materials.

In some embodiments, the method includes providing a first plurality of solar cells 1006. In some embodiments, the method includes providing a second plurality of solar cells 1008. In some embodiments, the first plurality of solar cells 1006 and the second plurality of solar cells 1008 is between the first layer 1002 and the second layer 1004. In some embodiments, the first plurality of solar cells 1006 is offset laterally from the second plurality of solar cells 1008.

In some embodiments, the first layer 1002, the second layer 1004, the first plurality of solar cells 1006, and the second plurality of solar cells 1008 are positioned and located between an upper block 1050 and a lower block 1052. In some embodiments, one end 1054 of the upper block 1050 includes a raised portion 1056. In some embodiments, one end 1058 of the lower block 1052 includes a recessed portion 1060. In some embodiments, the raised portion 1056 of the upper block 1050 is opposed to the recessed portion 1060 of the lower block 1052. In some embodiments, the size and shape of the raised portion 1056 of the upper block 1050 is complimentary to the recessed portion 1060 of the lower block 1052. In some embodiments, the raised portion 1056 of the upper block 1050 has opposed obliquely extending tapered portions 1062. In some embodiments, the recessed portion 1060 of the lower block 1052 has opposed obliquely extending tapered portions 1064. In some embodiments, the raised portion 1056 and/or the recessed portion 1060 may include other shapes and sizes.

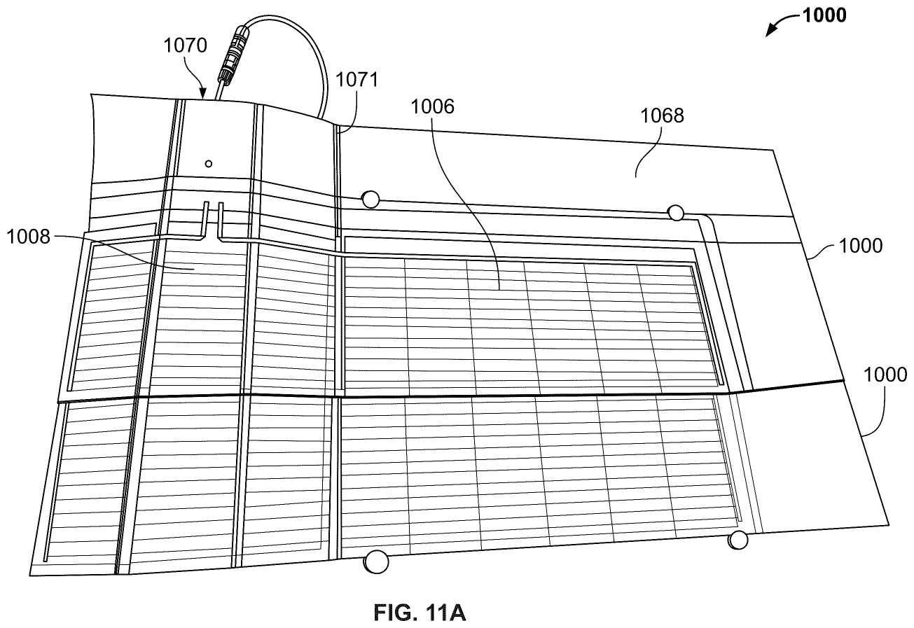

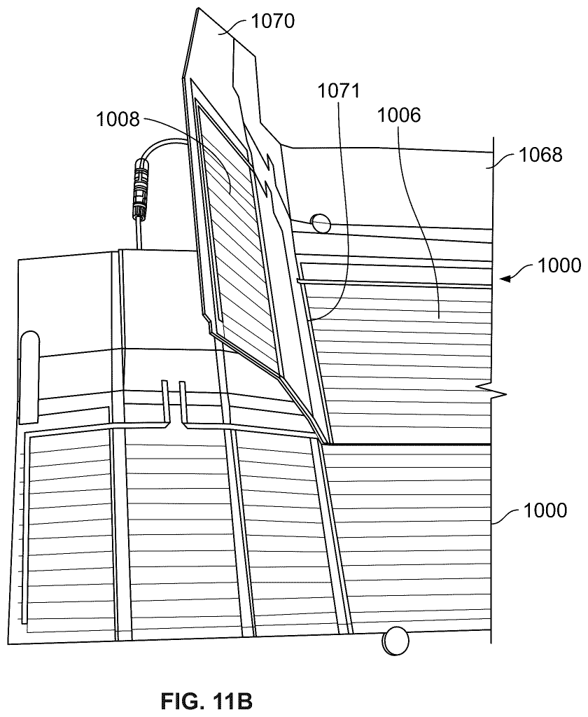

In some embodiments, the upper block 1050 and lower block 1052 thermoform the photovoltaic module 1000 with heat and pressure to achieve a desired shape of the photovoltaic module 1000. In some embodiments, the first plurality of solar cells 1006 and the second plurality of solar cells 1008 are encapsulated between the first layer 1002 and the second layer 1004. In some embodiments, the first plurality of solar cells 1006 is located in a first portion 1068 of the photovoltaic module 1000. In some embodiments, the second plurality of solar cells 1008 is located in a second portion 1070 of the photovoltaic module 1000. In some embodiments, the second portion 1070 is adjacent or proximate the first portion 1068. In some embodiments, a hinged portion 1071 is between the first portion 1068 and the second portion 1070. In some embodiments, the first portion 1068 extends in a first plane. In some embodiments, the second portion 1070 extends in a second plane. In some embodiments, the second plane is offset from the first plane. In some embodiments, the second plane is offset from the first plane when the photovoltaic module 1000 is installed on a roof deck. In some embodiments, the second portion 1070 is a wireway 1072 when the photovoltaic module 1000 is installed on a roof deck. In some embodiments, the second portion 1070 includes a trapezoidal shape. In some embodiments, with additional reference to FIGS. 11A and 11B, the hinged portion 1071 is flexible and enables the second portion 1070 to rotate relative the first portion 1068.

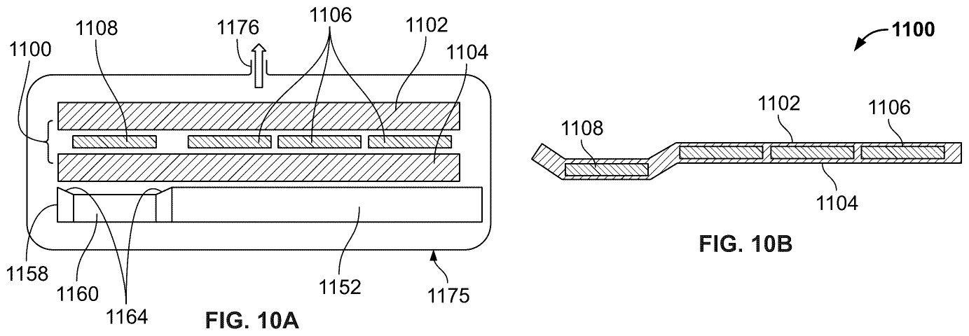

FIGS. 10A and 10B illustrate embodiments of a method of making a photovoltaic module 1100. In some embodiments, the photovoltaic module 1100 has a structure, composition, function, and features similar to the photovoltaic modules described above including the photovoltaic module 1000, except as otherwise noted. In some embodiments, the method includes providing a first layer 1102. In some embodiments, the first layer 1102 is a frontsheet of the photovoltaic module 1100. In some embodiments, the first layer 1102 is composed of a polymer. In some embodiments, the first layer 1102 is composed of a composite material. In some embodiments, the first layer 1102 is composed of a prepreg composite material. In some embodiments, the prepreg composite material includes a reinforcing fabric, such as carbon fiber or fiberglass pre-impregnated with a resin system, such as epoxy.

In some embodiments, the method includes providing a second layer 1104. In some embodiments, the second layer 1104 is a backsheet of the photovoltaic module 1100. In some embodiments, the second layer 1104 is below the first layer 1102. In some embodiments, the second layer 1104 is composed of a polymer. In some embodiments, the second layer 1104 is composed of a composite material. In some embodiments, the second layer 1104 is composed of a prepreg composite material, such as the above-referenced materials.

In some embodiments, the method includes providing a first plurality of solar cells 1106. In some embodiments, the method includes providing a second plurality of solar cells 1108. In some embodiments, the first plurality of solar cells 1106 and the second plurality of solar cells 1008 is between the first layer 1102 and the second layer 1104. In some embodiments, the first plurality of solar cells 1106 is offset laterally from the second plurality of solar cells 1108.

In some embodiments, the first layer 1102, the second layer 1104, the first plurality of solar cells 1106, and the second plurality of solar cells 1108 are positioned and located above a lower block 1152. In some embodiments, the first layer 1102, the second layer 1104, the first plurality of solar cells 1106, and the second plurality of solar cells 1108 are positioned and located above a lower block 1152 are located within a vacuum chamber 1175. In some embodiments, one end 1054 of the upper block 1050 includes a raised portion 1056. In some embodiments, one end 1158 of the lower block 1052 includes a recessed portion 1160. In some embodiments, the recessed portion 1160 of the lower block 1152 has opposed obliquely extending tapered portions 1164. In some embodiments, the recessed portion 1160 may include other shapes and sizes.

In some embodiments, the vacuum chamber 1175 includes a vacuum port 1176. In some embodiments, the vacuum chamber 1175 and in turn the first layer 1102, the second layer 1104 are subject to heat and a pull vacuum through the vacuum port 1176 pulls the components of the photovoltaic module 1100 and the lower block 1152 to form the photovoltaic module 1100 to achieve a desired shape of the photovoltaic module 1100, such as that shown in FIG. 10B.

Variations, modifications, and alterations to embodiments of the present disclosure described above will make themselves apparent to those skilled in the art. All such variations, modifications, alterations and the like are intended to fall within the spirit and scope of the present disclosure, limited solely by the appended claims.

While several embodiments of the present disclosure have been described, it is understood that these embodiments are illustrative only, and not restrictive, and that many modifications may become apparent to those of ordinary skill in the art. For example, all dimensions discussed herein are provided as examples only, and are intended to be illustrative and not restrictive.

Any feature or element that is positively identified in this description may also be specifically excluded as a feature or element of an embodiment of the present as defined in the claims.

The disclosure described herein may be practiced in the absence of any element or elements, limitation or limitations, which is not specifically disclosed herein. The terms and expressions which have been employed are used as terms of description and not of limitation, and there is no intention in the use of such terms and expressions of excluding any equivalents of the features shown and described or portions thereof, but it is recognized that various modifications are possible within the scope of the disclosure.

What is claimed is:

1. A method, comprising:
obtaining a plurality of components,
wherein the plurality of components comprises at least:
a frontsheet,
solar cells, and
a backsheet;
positioning the plurality of components such that:
a first row of solar cells is above the backsheet,
a second row of solar cells is above the backsheet, and
the frontsheet is above at least one of the first row of solar cells or the second row of solar cells; and
laminating the plurality of components to form a photovoltaic module,
wherein the photovoltaic module includes a first portion and a second portion,
wherein the first portion of the photovoltaic module includes the first row of solar cells,
wherein the second portion of the photovoltaic module includes the second row of solar cells,
wherein the first portion of the photovoltaic module extends along a first plane,
wherein the second portion of the photovoltaic module extends along a second plane, and
wherein the second plane is offset from the first plane, thereby forming a wireway in the second plane.

2. The method of claim 1, wherein the laminating comprises laminating at a temperature of 140 degrees C. to 180 degrees C.

3. The method of claim 1, wherein the laminating comprises laminating at a pressure of 0.5 bar to 1 bar.

4. The method of claim 1, wherein the backsheet comprises a polymer material.

5. The method of claim 1, wherein the backsheet comprises at least one of a polyolefin elastomer (POE), a dielectric material, a thermoplastic polyolefin (TPO), or a continuous fiber tape (CFT).

6. The method of claim 1, wherein the frontsheet comprises:
a polymer layer, and
a glass layer,
wherein the polymer layer is an outer layer of the photovoltaic module.

7. The method of claim 6, wherein the polymer layer comprises at least one of an ethylene tetrafluoroethylene (ETFE) or a polyolefin elastomer (POE).

8. A method, comprising:
obtaining a plurality of components,
wherein the plurality of components comprises at least:
a frontsheet,
solar cells, and
a backsheet;
positioning the plurality of components such that:
a first row of solar cells is above the backsheet,
a second row of solar cells is above the backsheet, and
the frontsheet is above at least one of the first row of solar cells or the second row of solar cells; and
vacuum forming the plurality of components with one another to form a photovoltaic module,
wherein the photovoltaic module has a first portion and a second portion,
wherein the first portion of the photovoltaic module includes the first row of solar cells,
wherein the second portion of the photovoltaic module includes the second row of solar cells,
wherein the first portion of the photovoltaic module extends along a first plane,
wherein the second portion of the photovoltaic module extends along a second plane, and
wherein the second plane is offset from the first plane, thereby forming a wireway in the second plane.

9. The method of claim 8, wherein the vacuum forming comprises vacuum forming at a temperature of 140 degrees C. to 180 degrees C.

10. The method of claim 8, wherein the vacuum forming comprises vacuum forming at a pressure of 0.5 bar to 1 bar.

11. The method of claim 8, wherein the backsheet comprises a polymer material.

12. The method of claim 8, wherein the backsheet comprises at least one of a polyolefin elastomer (POE), a dielectric material, a thermoplastic polyolefin (TPO), or a continuous fiber tape (CFT).

13. The method of claim 8, wherein the frontsheet comprises:
a polymer layer, and
a glass layer,
wherein the polymer layer is an outer layer of the photovoltaic module.

14. The method of claim 13, wherein the polymer layer comprises at least one of an ethylene tetrafluoroethylene (ETFE) or a polyolefin elastomer (POE).

15. A method, comprising:
obtaining a plurality of components,
wherein the plurality of components comprises at least:
a frontsheet,
solar cells, and
a backsheet;
positioning the plurality of components such that:
a first row of solar cells is above a first portion of the backsheet,
a second row of solar cells is above a second portion of the backsheet, and
the frontsheet is above at least one of the first row of solar cells and the second row of solar cells;
laminating the plurality of components to form a photovoltaic module,
wherein the photovoltaic module has a first portion and a second portion,
wherein the first portion includes the first row of solar cells,
wherein the second portion includes the second row of solar cells;
heating the photovoltaic module, thereby providing a heated photovoltaic module; and
thermoforming the heated photovoltaic module, thereby repositioning the second portion of the photovoltaic module relative to the first portion such that:
the first portion of the photovoltaic module extends along a first plane, and
the second portion of the photovoltaic module extends along a second plane,
wherein the second plane is offset from the first plane, thereby forming a wireway in the second plane.

16. The method of claim 15, wherein the laminating comprises laminating at a temperature of 140 degrees C. to 180 degrees C., and wherein the laminating comprises laminating at a pressure of 0.5 bar to 1 bar.

17. The method of claim 15, wherein the heating the photovoltaic module comprises heating to a temperature of 140 degrees C. to 180 degrees C.

18. The method of claim 15, wherein, prior to the heating the photovoltaic module, the method comprises cooling the photovoltaic module.

19. The method of claim 15, wherein the thermoforming comprises vacuum thermoforming at a temperature of 120 degrees C. to 160 degrees C., and a pressure of 0.5 bar to 1 bar.

20. The method of claim 15, wherein the thermoforming comprises mechanical thermoforming at a temperature of 120 degrees C. to 160 degrees C., and a pressure of 0.5 bar to 2 bar.
